(19) United States
(12) Patent Application Publication
(10) Pub. No.: US 2009/0098666 A1
(43) Pub. Date: Apr. 16, 2009

(54) CHIP PACKAGE ASSEMBLY USING CHIP HEAT TO CURE AND VERIFY

(75) Inventors: Ronald L. Hering, Pleasant Valley, NY (US); Kathryn C. Rivera, Hopewell Junction, NY (US); Kamal K. Sikka, Poughkeepsie, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/870,571

(22) Filed: Oct. 11, 2007

(51) Int. Cl. H01L 21/66

(52) U.S. Cl. 438/15; 257/E21.521

(57) ABSTRACT

Methods of assembling a chip package are disclosed that employ heat from test pattern operation of the chip to cure a thermal interface material. The methods may also simultaneously verify thermal performance of the package using the heat from test pattern operation. Further, the heat may be used to cure the sealing material and/or underfill material, where they are used.

### BACKGROUND

1. Technical Field

The disclosure relates generally to integrated circuit (IC) chip packaging, and more particularly, to methods of assembling a chip package.

2. Background Art

In the integrated circuit (IC) chip packaging industry, a chip package is assembled and then tested to verify that it is operating correctly. The assembly process can include a measurement of chip and lid heights to indirectly determine the thermal interface material (TIM) gap as an indicator of the thermal performance of the assembled package. The assembly process finishes with performing a cure of the TIM and/or sealing materials, or a mechanical assembly of the lid to the substrate. Thermal performance verification of the chip package using an in-system setting or special thermal testers to heat the chip is then performed to ensure the package is operating correctly.

### SUMMARY

Methods of assembling a chip package are disclosed that employ heat from test pattern operation of the chip to cure a thermal interface material. The methods may also simultaneously verify thermal performance of the package using the heat from test pattern operation. Further, the heat may be used to cure the sealing material and/or underfill material, where they are used.

A first aspect of the disclosure provides a method of assembling a chip package, the method comprising: coupling a chip to a substrate; forming a thermal interface material (TIM) over the chip; and assembling the chip package by coupling a lid over the chip using heat from test pattern operation of the chip to cure the TIM.

A second aspect of the disclosure provides a method of assembling a chip package, the method comprising: coupling a chip to a substrate; forming a thermal interface material (TIM) over the chip; forming a sealing material between the substrate and a lid; assembling the chip package by coupling the lid over the chip using heat from test pattern operation of the chip to cure the TIM and the sealing material; and performing thermal performance verification of the chip during the assembling.

A third aspect of the disclosure provides a method of assembling a chip package, the method comprising: coupling a chip to a substrate, wherein the coupling includes forming an underfill material under the chip; forming a thermal interface material (TIM) over the chip; forming a sealing material between the substrate and a lid; assembling the chip package by coupling the lid over the chip using heat from test pattern operation of the chip to cure the TIM, the sealing material and the underfill material; and performing thermal performance verification of the chip during the assembling.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1A-1D show a non-exhaustive set of IC chip packages to which embodiments of a method according to the disclosure may be applied.

It is noted that the drawings of the disclosure are not to scale. The drawings are intended to depict only typical aspects of the disclosure, and therefore should not be considered as limiting the scope of the disclosure. In the drawings, common numbering represents common elements between the drawings.

### DETAILED DESCRIPTION

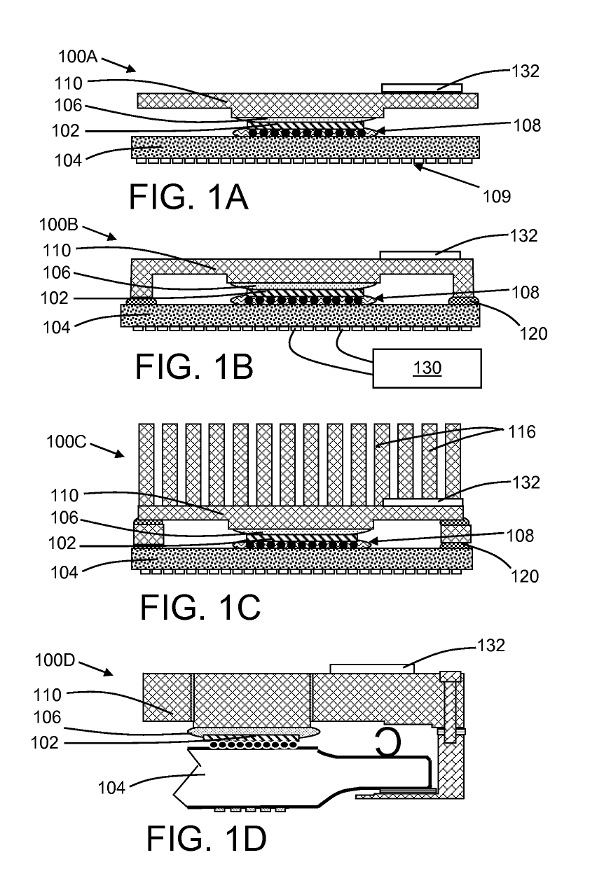

FIGS. 1A-1D show a non-exhaustive set of IC chip packages 100A-D, respectively, to which embodiments of a method according to the disclosure may be applied. An initial process includes coupling a chip 102 to a substrate 104. Chip 102 may be coupled to substrate 104 in any now known or later developed manner, e.g., by a controlled collapse chip connect (C4) grid array which may (FIGS. 1A-1C) or may not be (FIG. 1D) encapsulated by a polymer underfill 108. Substrate 104 may take the form of a plastic laminate or a ceramic chip carrier, and may carry a single chip or multiple chips. Each chip 102 may include any now known or later developed manner of integrated circuit chip. Chip carrier 104 may have ball grid, column grid, wirebond or land grid array pads 109 or any other technologies developed later.

A next process includes forming a thermal interface material (TIM) 106 over chip 102 for thermally coupling the chip to a lid 110. TIM 106 may include any material for filling the gap between chip 102 and lid 110 in order to increase thermal transfer efficiency, e.g., paste or thermal grease (typically silicone or hydrocarbon oil filled with aluminum oxide, zinc oxide, boron nitride, or indium); thermal pads; epoxy or gel adhesive (silver-filled or otherwise); a phase-change material (PCM); or a metal thermal interface. Lid 110 may include any material for spreading heat (e.g., a metal or composite), and may include a planar cover (FIG. 1A), a hollowed cover (FIG. 1B), a cover with heat spreading fins 116 (FIG. 1C), a copper hat with a piston (FIG. 1D) or any other later developed chip covering. Lid 110 may be held in place by TIM 106 alone (FIG. 1A), by sealing material 120 (FIGS. 1B-1C) or by mechanical fasteners (FIG. 1D). Forming TIM 106 “over” chip 102 may include literally forming TIM 106 on chip 102 or forming TIM 106 on lid 110, which is later positioned over chip 102.

Chip package 100 is then assembled by coupling lid 110 over chip 102 using heat from test pattern operation of the chip to cure the TIM. That is, rather than baking chip package 100 in an oven or a furnace, heat generated from operation of chip 102 on a test pattern is used to cure TIM 106. The test pattern used can be user specified. In addition, if a sealing material 120 is used between substrate 104 and lid 110 (FIGS. 1B-1C), the assembling may include using the heat from test pattern operation of chip 102 to cure sealing material 120. Underfill material 108 under chip 102, where provided (FIGS. 1A-1C) may also be cured in this manner.

In addition to the assembly of chip package 100A-100D, a method according to the disclosure may also include performing thermal performance verification of chip 102 during the assembly. The chip temperature can be monitored using any conventional on-chip temperature sensor (OCTS). The OCTS can be calibrated (e.g., using e-fuses on chip 102) to accommodate the temperature of the assembling, which may be higher than typically experienced by chip 102. Furthermore, a temperature of lid 110 may be monitored using a detachable thermocouple 132 contacting the lid. Alternatively, or in addition thereto, monitoring of temperature using the OCTS and/or supplying chip power can be achieved by employing a temporary adapter socket 130 coupled to the substrate. The package thermal resistance can then be verified by measuring the chip power dissipated in the chip and the temperature difference between the chip and lid.

The above-described process achieves temperatures required for assembly of chip package 100A-100D, and allows measurement of thermal performance during the assembly process by using the chip heat and adjustment of cooling conditions. The process also allows for wet rework, for example, when a lid needs to be removed prior to cure without doing post capping testing. Hence, the process improves assembly yield, eliminates assembly equipment such as ovens or furnaces and results in time and cost-reduction of assembly and test operations. There is also flexibility in where the process can be implemented: during chip package test, burn-in, or at systems test. It is understood that while the disclosure has been described relative to four illustrative chip packages, the teachings of the disclosure are applicable to a variety of chip package structures not expressly disclosed herein.

The method as described above is used in the fabrication of integrated circuit chip packages. The integrated circuit chips can be distributed by the fabricator in raw wafer form (that is, as a single wafer that has multiple unpackaged chips), or as a bare die. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). The above-described methods may be applied to either type of package. In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1.-20. (canceled)

21. A method of assembling a chip package, the method comprising:
coupling a chip to a substrate, wherein the coupling includes forming an underfill material under the chip;
forming a thermal interface material (TIM) over the chip;
forming a sealing material between the substrate and a lid;
assembling the chip package by coupling the lid over the chip using heat from test pattern operation of the chip to cure the TIM, the sealing material and the underfill material,
monitoring a temperature of the chip during the assembling using an on-chip temperature sensor (OCTS); and
performing thermal performance verification of the chip during the assembling.
